(19) United States
(12) Patent Application Publication
(10) Pub. No.: US 2007/0262326 A1
(43) Pub. Date: Nov. 15, 2007

(54) LED multi-layer metals primary electrodes manufacturing process & installation

(75) Inventor: Chi-Te Liao, Cingshuei Township (TW)

Correspondence Address: TROXELL LAW OFFICE PLLC, SUITE 1404, 5205 LEESBURG PIKE, FALLS CHURCH, VA, 22041, US

(73) Assignee: TOUCHTEK CORPORATION

(21) Appl. No.: 11/430,919

(22) Filed: May 10, 2006

(51) Int. Cl. H01L 33/00; H01L 31/12; H01L 27/15; H01L 29/26

(52) U.S. Cl. 257/79

(57) ABSTRACT

Primary electrodes process and installation for manufacturing of LED multi-layer metals comprised of having epitaxial wafer cleaned up and placed in the manufacturing installation to undergo multi-metal electrodes process; installation include a loader, a magnetic device, a carrier, a magnetic mask, and multiple-layer metal sources for epitaxial wafer loaded by the carrier to form multiple metal electrodes through deposition of contact window adapted to the magnetic mask using the metal coating deposition method.

### BACKGROUND OF THE INVENTION

(a) Field of the Invention

The present invention is related to LED multi-layer metals primary electrodes manufacturing process and installation, and more particularly, to the use of metal coating deposition method to have the multi-metal source deposited through contact window of magnetic mask in the manufacturing of the metal electrode.

(b) Description of the Prior Art

Whereas an LED relates to a solid electronic installation of semiconductor photo-electric device containing one P and one N electrodes to emit light by conducting an extremely low amperage through where between both electrodes; the light emission is considered as a cold light emission by incorporating electrons and electric holes instead of emitting light by heating a filament of a light bulb with externally applied source. LED features compact in size, small power consumption, fast speed, high reliability and long service life. LED offers comprehensive applications including adaptation to indicator, display, outdoor signboard, handset backlight source and LCD backlight source. The manufacturing process of those LEDs generally available in the market involve the selection of the base material including Gap substrate, i.e., the 2-element base material or GaAsP substrate, the 3-element base material, and even the AlInGaP substrate, i.e., the 4-element base material in meeting higher luminance and higher power.

Later, the process involves manufacturing of multi-layer metal electrodes on epitaxial wafer. In the first step, S1, the conventional multi-layer metal electrodes manufacturing process as illustrated in FIG. 6, the AlInGaP epitaxial wafer is cleaned up; S2, the clean epitaxial wafer undergoes a primary coating by evaporation (AuBe and Au); S3, primary yellow light development into patterned photo resist layer; S4, the primary metal chemical etching to form the metal patter; S5, the primary thermal treatment; S6, the secondary metal (Ti and Au) coating by evaporation; S7, the secondary yellow light development to from photo resist; S8, the secondary chemical etching process; and finally, S9, the second thermal treatment to complete the LED multi-layer metal electrodes to achieve conduction between metal electrodes and materials in the fashion of ohmic contact. However, the manufacturing technology of the prior art requires coating, development and etching processes respectively done for the secondary coating layer; and is found much more complicated even though the manufacturing technology of the prior art is considered highly matured. Furthermore, there are inherited problems found with the prior art including over etching of the metal, and strip-off or insufficient push or pull of metal due to poor contact of the interface between the primary and the secondary multi-layer metals or excessively etched to the secondary layer.

### SUMMARY OF THE INVENTION

The primary purpose of the present invention is to provide primary electrodes manufacturing process and installation for LED multi-layer metals without the yellow development or wet chemical etching or photo resist relief process to complete manufacturing the multi-layer metal electrodes in a primary process. To achieve the purpose, the epitaxial wafer is cleaned up and placed in the manufacturing installation including an evaporation coating magazine, a magnetic member, a carrier, a magnetic mask, and multiple metal sources. The epitaxial wafer is loaded in the carrier and multiple metal sources form multi-layer metal electrodes through metal coating deposition of the contact window adapted to the magnetic mask. The magnetic mask is disposed over the wafer and the magnetic member at the bottom of the carrier is attracted to the magnetic mask to hold steady the epitaxial wafer. Upon completing the formation of multi-layer metal electrodes with the magnetic mask and carrier removed, a thermal treatment is followed to complete the LED

### BRIEF DESCRIPTION OF THE DRAWINGS

FIG. 1 is a flow chart showing the manufacturing process of primary electrodes for multi-layer metals of the present invention.

FIG. 2 is a schematic view showing a construction of a manufacturing installation of primary electrodes for multi-layer metals of the present invention.

FIG. 3 is a flow chart showing a preferred embodiment of a manufacturing process of primary electrodes for multi-layer metals of the present invention.

FIG. 4 is a schematic view showing a construction of the primary electrodes of multi-layers metals after evaporation coating of the present invention.

FIG. 5 is a schematic view showing a construction of the present invention with magnetic mask and carrier removed.

FIG. 6 is a flow chart showing the manufacturing process of primary electrodes for multi-layer metals of the prior art.

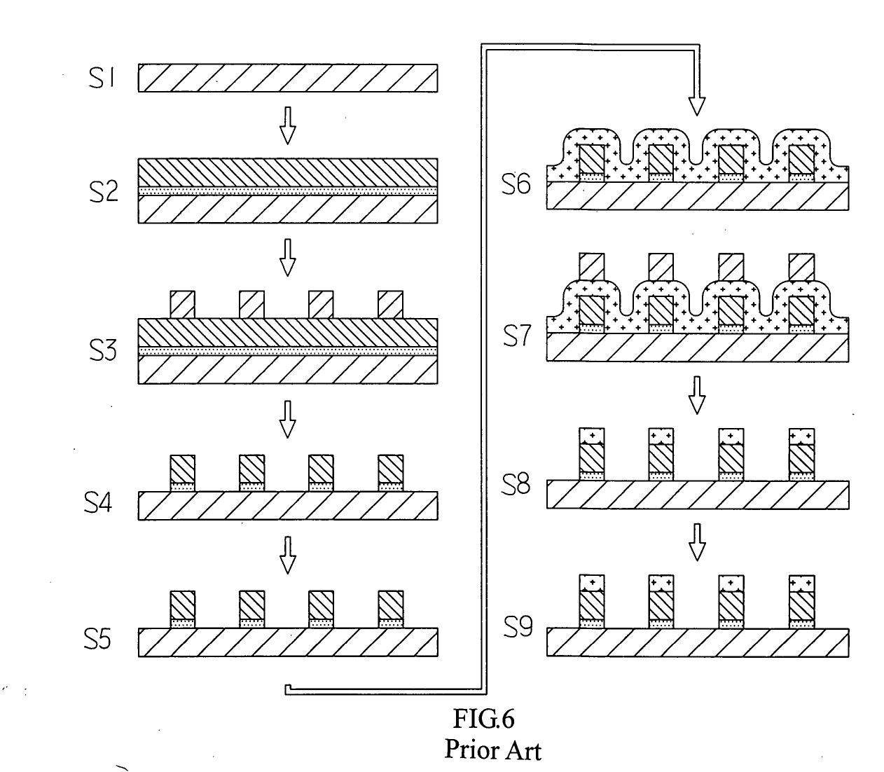

### DETAILED DESCRIPTION OF THE PREFERRED EMBODIMENTS

The present invention relates to manufacturing process and installation of primary electrodes for LED multi-layer metals without yellow light develop and we chemical etching steps to direct carry out multi-layer film deposition to complete the manufacturing of metal electrodes by using a specially designed carrier and having a magnetic device and magnetic mask attached to the surface of a epitaxial wafer.

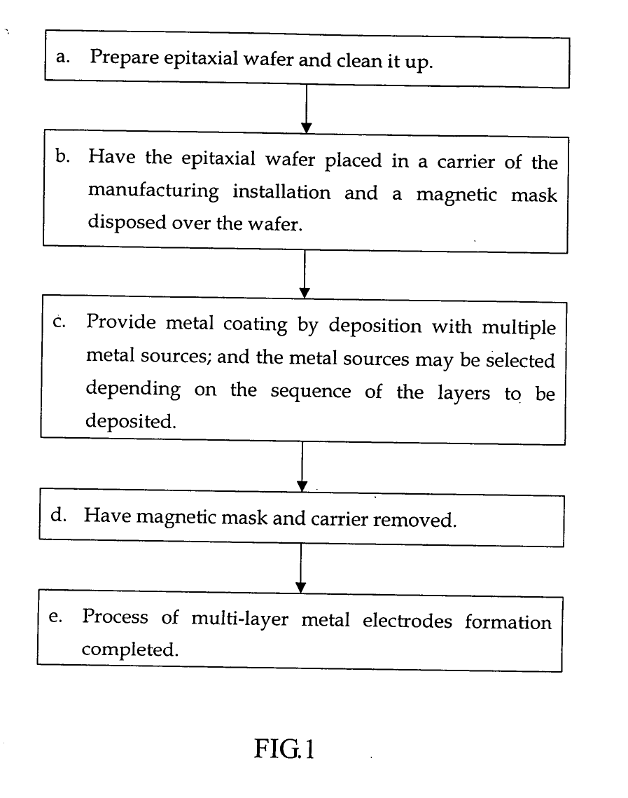

Referring to FIG. 1 for a flow chart showing a manufacturing process of LED metal electrodes of the present invention, the surface of a LED epitaxial wafer is cleaned up before coating as illustrated in Step a using acid or alkali chemical agent to remove oxides, contaminants, and metal ions found on the surface of the epitaxial wafer. The chemical agent used in the cleaning process is essentially comprised or any one or two types of inorganic solutions mixed in proper ratios selected from sulfuric acid, nitric acid, hydrogen peroxide, phosphoric acid, and hydrochloric acid.

In Step b, the clean epitaxial wafer is placed in a carrier of the manufacturing installation and a magnetic mask is disposed over the wafer. In Step c, multiple metal sources are used to carry out the metal coating deposition with metal sources selected depending on the sequence of the layers to be deposited. Upon completing the deposition, the magnetic mask and the carrier are removed in Step d to complete the formation of multi-layer metal electrodes in Step e.

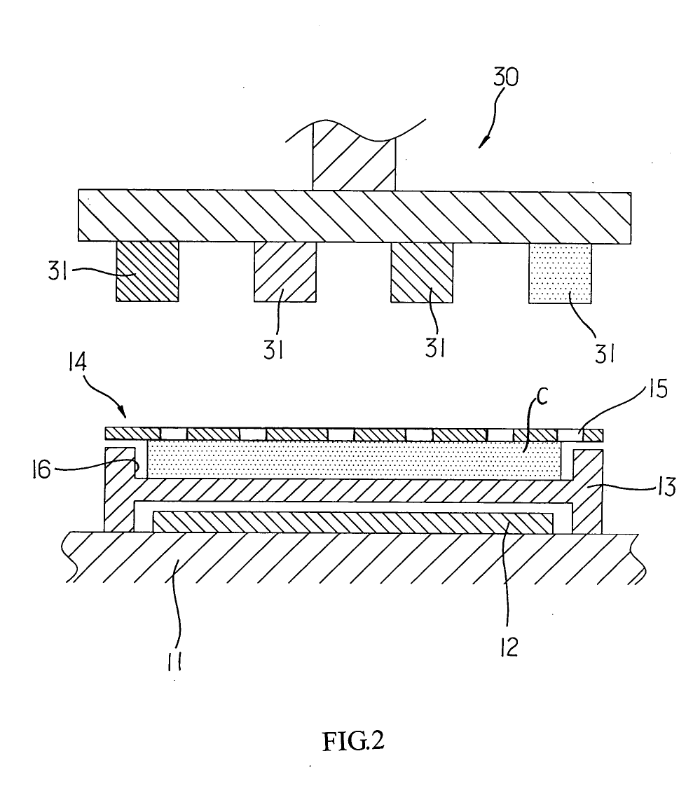

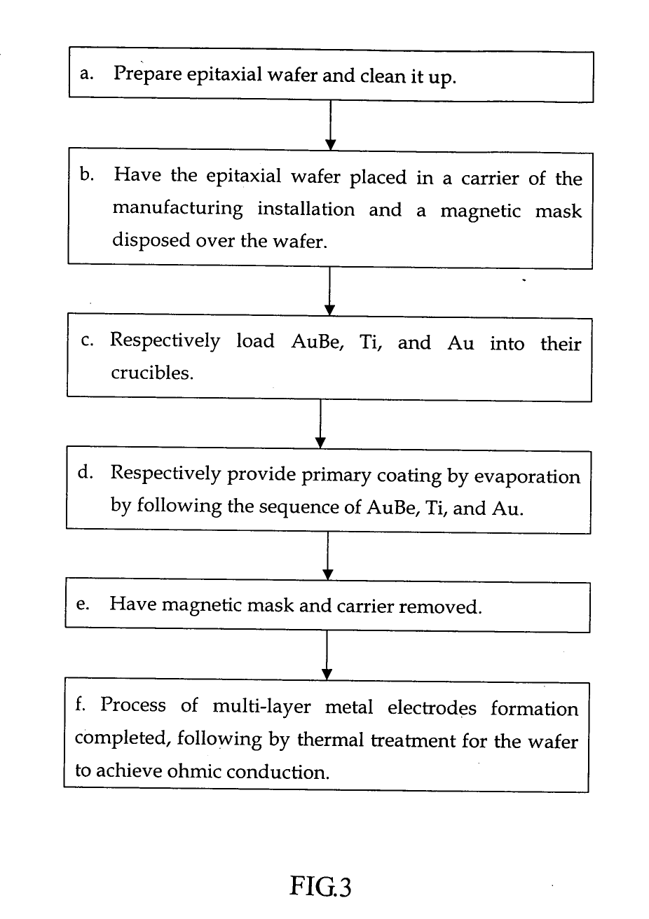

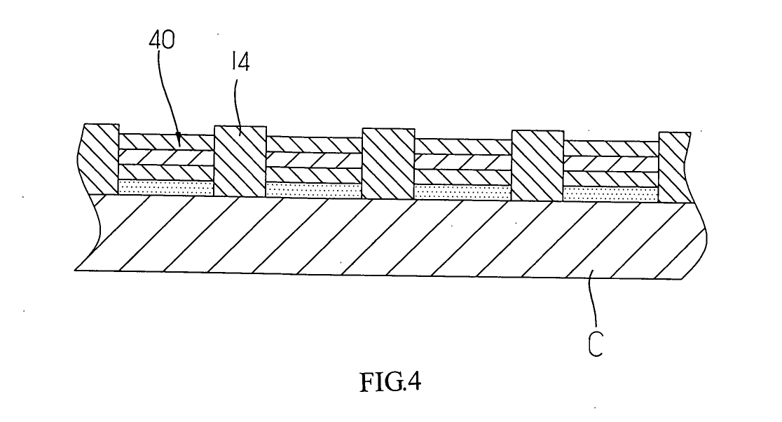

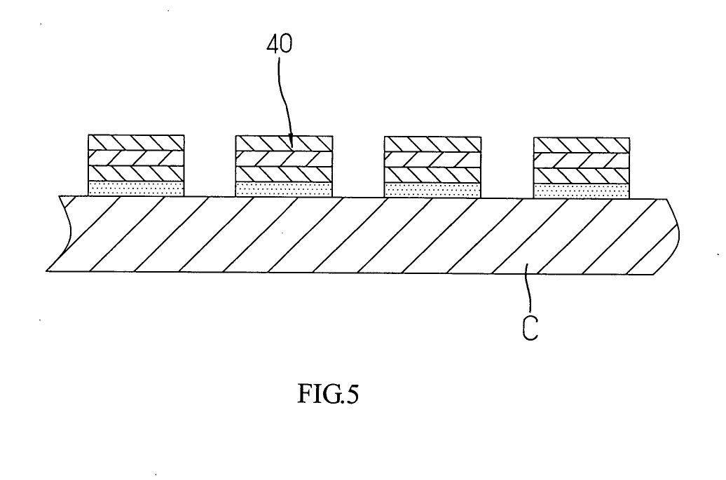

The manufacturing installation 10 of the present invention as illustrated in FIG. 2 includes a support 11; a carrier 13 containing a slot 16 to accommodate an epitaxial wafer C being provided on the support 11; a magnetic device 12 usually made of magnetic material including AlFeB, SmCo, or oxidized magnet being separately provided between the support 11 and the carrier 13; a magnetic mask 14 already placed in the slot 16 of the carrier 13 being related to a soft film made of a magnetic stainless steel or nickel iron alloy in thickness ranging between 10˜300 μm and 30 μm preferred being provided over the epitaxial wafer C; multiple contact windows 15 being disposed on the magnetic mask 14 for the formation of multi-layer metal electrodes; and multiple metal sources 30 to be placed in their respective crucibles 31 depending on the metal materials designated for process. In the preferred embodiment, those crucibles 31 respectively loaded with AuBe, Ti, and Au metal liquids are arranged in linear or circle. Also as illustrated in FIG. 3 for a schematic view of the manufacturing process of the LED multi-layer metal electrodes, the epitaxial wafer is cleaned up and placed in the carrier with a magnetic mask disposed over the wafer. The magnetic mask 14 is attached to the epitaxial wafer C so that the magnetic device 12 at the bottom of the carrier 13 is attracted to the metal magnetic mask 14 to firmly secure the epitaxial wafer C in the slot 16 of the carrier 13. AuBe, Ti, and Au are respectively loaded in corresponding crucibles 31 to undergo metal coating deposition (by evaporation in the preferred embodiment) in the sequence of AuBe, Ti, and Au. The frequency of the metal coating deposition for AuBe, Ti, and Au may be selected. For example, in the preferred embodiment, the deposition sequence has Au on the top layer allowing direct formation of multi-layer metal electrodes 40 on the surface of epitaxial C, i.e., at where those contact windows are located as illustrated in FIG. 4. Finally, as illustrated in FIG. 5, the wafer C is left in an oven tube at the temperature of 300˜1000° C. for 5˜50 minutes to achieve ohmic contact between the surface of the wafer C and metal electrodes to produce integral metal electrodes.

Wherein in the present invention, the metal evaporation source radiates to the wafer at a practically right angle, very consistent metal electrodes are formed on the wafer. In addition to extending the length and width of the reaction chamber, the curvature of the evaporation coating disk may be made smaller (close to that of a direct radiation line) so that the metal evaporation source is capable of achieving an incidence to the wafer at a practically right angle.

Accordingly, without relying upon the yellow light development process and the wet chemical metal etching process for metal, the manufacturing installation of the present invention provides easy and fast process with significant reduction of the production cost to solve those defects found with the yellow light development process and the wet chemical metal etching process of the prior art.

The preferred embodiment described above serves for the purpose only for describing the teaching and characteristics of the present invention so that any one who is familiar with the art is able to understand the contents and practice accordingly. Therefore, it is should noted that the preferred embodiment disclosed in the specification and the accompanying drawings are not limiting the present invention; and that any change or modification made equivalent to the teaching of the present invention should fall within the scope of the purposes and claims of the present invention.

I claim:

1. Primary electrodes process and installation for manufacturing of LED multi-layer metals includes the following steps:
a. Clean up an epitaxial wafer;
b. Place the clean epitaxial wafer in a carrier of a manufacturing installation, and provide a magnetic mask containing multiple contact windows over the wafer;
c. Multiple metal sources loaded with different metal materials are provided to stack up on the wafer multiple layers of metal electrodes in sequence through those contact windows by using the metal coating deposition method; and
d. Remove the manufacturing installation.

2. Primary electrodes process and installation for manufacturing of LED multi-layer metals of claim 1, wherein acid or alkali chemical agents are used to clean up the surface of the epitaxial wafer.

3. Primary electrodes process and installation for manufacturing of LED multi-layer metals of claim 2, wherein the chemical agents are essentially comprised of inorganic solutions including sulfuric acid, nitric acid, hydrogen peroxide, phosphoric acid, and hydrochloric acid.

4. Primary electrodes process and installation for manufacturing of LED multi-layer metals of claim 2, wherein a thermal treatment is provided after the completion of the final Step d.

5. Primary electrodes process and installation for manufacturing of LED multi-layer metals of claim 4, wherein the wafer is left in an oven tube at the temperature of 300˜1000° C. for 5˜50 minutes to achieve ohmic contact between the surface of the wafer C and metal electrodes.

6. Primary electrodes process and installation for manufacturing of LED multi-layer metals includes a support; a carrier disposed on the support and containing a slot to accommodate an epitaxial wafer; a magnetic device disposed between the support and the carrier; a magnetic mask adapted with multiple contact windows and placed on the epitaxial wafer with the magnetic device at the bottom of the carrier attracted to the magnetic mask to secure the epitaxial wafer onto the carrier; and multiple metal sources to load with pre-designated metal materials; wherein multiple metal sources stacking up on the wafer to form multi-layer metal electrodes through those contact windows by using the metal coating deposition method.

7. Primary electrodes process and installation for manufacturing of LED multi-layer metals of claim 6, wherein the magnetic material is related to AlFeB, SmCo, or oxidized magnet.

8. Primary electrodes process and installation for manufacturing of LED multi-layer metals of claim 6, wherein the magnetic mask related to a soft film made of magnetic stainless steel or nickel iron alloy.

9. Primary electrodes process and installation for manufacturing of LED multi-layer metals of claim 6, wherein the thickness of the magnetic mask falls within the range of 10˜300 μm.

10. Primary electrodes process and installation for manufacturing of LED multi-layer metals of claim 6, wherein the preferred thickness of the magnetic mask is 30 μm.

11. Primary electrodes process and installation for manufacturing of LED multi-layer metals of claim 6, wherein those crucibles are arranged in linear or circle.

12. Primary electrodes process and installation for manufacturing of LED multi-layer metals of claim 6, wherein those multiple metal sources are placed in corresponding crucibles depending on the types of pre-designated metal materials.

13. Primary electrodes process and installation for manufacturing of LED multi-layer metals of claim 12, wherein those metal materials are related to metal liquids of AuBe, Ti, and Au.

14. Primary electrodes process and installation for manufacturing of LED multi-layer metals of claim 13, wherein those metal materials are given the coating deposition process in sequence of AuBe, Au, and Ti with Au at the top layer.
